(19) United States
(12) Patent Application Publication
(10) Pub. No.: US 2014/0284768 A1
(43) Pub. Date: Sep. 25, 2014

(54) SEMICONDUCTOR ON INSULATOR STRUCTURE WITH IMPROVED ELECTRICAL CHARACTERISTICS

(71) Applicant: Soitec, Crolles Cedex (FR)

(72) Inventor: Konstantin Bourdelle, Crolles (FR)

(73) Assignee: SOITEC, Crolles Cedex (FR)

(21) Appl. No.: 14/360,447

(22) PCT Filed: Nov. 13, 2012
(86) PCT No.: PCT/IB2012/002349

§ 371 Date: May 23, 2014

(30) Foreign Application Priority Data
Dec. 5, 2011 (FR) 1161169

(51) Int. Cl. H01L 21/265; H01L 29/16; H01L 29/161; H01L 29/36; H01L 29/20

(52) U.S. Cl. CPC H01L 21/265; H01L 29/36; H01L 29/20; H01L 29/161; H01L 29/16
USPC 257/609; 257/607; 438/527

(57) ABSTRACT

A semiconductor structure comprising a first semiconductor layer, a bulk semiconductor layer, an insulation layer between the first semiconductor layer and the bulk semiconductor layer, a first implanted region that is at least partially within the insulation layer; and a second doped region that is at least partially within the bulk semiconductor layer, wherein the first implanted region has an implant profile that shows a maximum within the insulation layer and a tail extending within the bulk semiconductor layer so as to inhibit the diffusion of a second doping material of the second doped region within the insulation layer.

### CROSS-REFERENCE TO RELATED APPLICATIONS

This application is a national phase entry under 35 U.S.C. §371 of International Patent Application PCT/IB2012/002349, filed Nov. 13, 2012, designating the United States of America and published in English as International Patent Publication WO 2013/084035 A1 on Jun. 13, 2013, which claims the benefit under Article 8 of the Patent Cooperation Treaty and under 35 U.S.C. §119(e) to French Patent Application Serial No. 1161169, filed Dec. 5, 2011, the disclosure of each of which is hereby incorporated herein in its entirety by this reference.

### TECHNICAL FIELD

The present invention relates to the field of semiconductors. More specifically, it relates to a semiconductor structure comprising a first semiconductor layer, a bulk semiconductor layer, an insulation layer between the first semiconductor layer and the bulk semiconductor layer, a first implanted region and a second doped region.

### BACKGROUND

Silicon on oxide (SOI) or ultra-thin buried oxide (UTBOX) wafers are advantageously characterized by small variations of the threshold-voltage and, thus, of growing interest in present and future CMOS technology. In particular, the fully depleted CMOS technology enables low-voltages and low-power circuits operating at high speeds. Moreover, fully depleted SOI devices are considered as the most promising candidates for enabling reduced short channel effects (SCE), particularly with the nodes below 22 nm.

Silicon on Insulator (SOI) wafers form the basis for the high-performance MOSFET and CMOS technology. The control of the SCE is mainly facilitated by the thinness of the active silicon layer formed above the insulator, i.e., buried oxide (BOX) layer. In order to reduce the coupling effect between source and drain and, furthermore, with respect to the scalability of thin film devices for future technologies, the provision of very thin BOX layers is mandatory. The control of the threshold voltage also depends on the thinness of the BOX layers. An appropriate implantation of the substrate below the BOX layer leads to the formation of back gate and enables an accurate adjustment of the threshold voltage by back gate biasing.

Accordingly, in order to provide a reliable and performing double-gate transistor on a SOI wafer, it is important to achieve a good control over the back gate, and over the BOX layer.

FIGS. 5a-5d illustrate semiconductor structures 5100-5300 according to the prior art.

As can be seen in FIG. 5a, semiconductor structure 5100 includes a first semiconductor layer 5101, an insulation layer 5102 and a bulk semiconductor layer 5103. The insulation layer 5102 is placed between the first semiconductor layer 5101 and the bulk semiconductor layer 5103, so as to electrically separate them.

The first semiconductor layer 5101 could be, for instance, Silicon. The insulation layer 5102 could be, for instance, Silicon Oxide. The bulk semiconductor layer 5103 could be, for instance, Silicon. With this exemplary arrangement, the semiconductor structure 5100 would be a SOI wafer, the insulation layer 5102 would be the BOX, and the bulk semiconductor layer 3013 could act as a back gate for transistors formed on the first semiconductor layer 5101.

In order to provide a better conductivity of the bulk semiconductor layer 5103, the semiconductor structure 5100 is doped via a doping step S51, as illustrated in FIG. 5b.

During the doping step S51, a doping material 5204 is implanted in the semiconductor structure 5100 so as to obtain the semiconductor structure 5200, illustrated in FIG. 5c. The doping can be done, for instance, by ion bombardment. For the formation of p-type ground plane, the doping material 5204 could be, for instance, Boron. The use of Boron is preferred to other materials such as In or BF2. This is due to the fact that In implants may result in the degradation of the BOX electrical properties due to the high mass of In and to its interaction with SiO2. BF2 implant, where the number of fluorine atoms is two times bigger than that of boron, may further result in a significant amount of F to be introduced in the Silicon. Such a combination of the B and F atoms may result in poor B activation.

However, pure Boron implants are not optimal since Boron has a tendency to diffuse and could segregate in the BOX, that is, in the insulation layer 5102.

For instance, as illustrated in FIGS. 5c and 5d, a certain number of doping atoms could be implanted in the semiconductor structures 5200 and 5300. More specifically, doping atoms 5205 and 5206 of the semiconductor structure 5200 could be the result of the implantation step S51. That is, even when the doping step S51 is carried out so as to form a doped region 5210 within the bulk semiconductor layer 5103 only, one or more doping atoms 5205 could be implanted in the first semiconductor layer 3013 and one or more doping atoms 5206 could be implanted in the insulation layer 3012.

Additionally, during a diffusing step S52, resulting in the semiconductor structure 5300 of FIG. 5d, the number of doping atoms 5205 and 5206 could increase, as indicated by doping atoms 5305 and 5306, due to the diffusion of doping material 5204 from the bulk semiconductor layer 5103 into the insulation layer 5102 and the first semiconductor layer 5101.

Such a diffusion of Boron into the insulation layer 5102 may adversely affect the electrical properties of the insulation layer 5102 because boron penetration increases charge trapping in SiO2 and degrades SiO2/Si interface properties, as disclosed in non-patent document “Impact Of Boron Penetration On Gate Oxide Reliability And Device Lifetime In P+-poly PMOSFETs” published in the Proceedings of Technical Papers of 1997 International Symposium on VLSI Technology, Systems, and Applications.

### BRIEF SUMMARY

It is, therefore, the object of the present invention to improve the process such that the diffusion can be reduced or prevented.

This object is achieved with the semiconductor structure comprising a first semiconductor layer; a bulk semiconductor layer; an insulation layer between the first semiconductor layer and the bulk semiconductor layer; a first implanted region that is at least partially within the insulation layer; and a second doped region that is at least partially within the bulk semiconductor layer; wherein the first implanted region has an implant profile that shows a maximum within the insulation layer and a tail extending within the bulk semiconductor layer so as to inhibit the diffusion of a second doping material of the second doped region within the insulation layer.

Thanks to such approach, it is possible to form a structure in which the insulation layer has good electrical characteristics.

In some embodiments the second doping material of the second doped region can be any of Boron, and/or BF2, and/or B18H22, and/or other boron-containing molecular species.

Thanks to such approach, a good electrical conductivity of the bulk semiconductor layer can be obtained.

In some embodiments, a first material of the first implanted region can be Fluorine, and/or Chlorine. In some embodiments, the first implanted region can have a thickness in the range of 40 nm to 80 nm, preferably of 75 nm.

Thanks to such approach, it is possible to effectively inhibit or at least reduce the diffusion of the second doping material and to improve the electrical characteristics of the insulation layer.

In some embodiments the second doped region can have a thickness in the range of 150 nm to 400 nm, preferably of 200 nm.

Thanks to such approach, a good electrical conductivity of the bulk semiconductor layer can be obtained.

In some embodiments, the first semiconductor layer can have a thickness in the range of 8 nm to 20 nm, preferably 12 nm, and/or the bulk semiconductor layer has a thickness (T3) in the range of 750 μm to 800 μm, preferably 775 μm, and/or the insulation layer has a thickness (T2) in the range of 8 nm to 40 nm, preferably 25 nm.

Thanks to such approach, good electrical characteristics of transistors formed on the first semiconductor layer can be achieved.

In some embodiments, the semiconductor structure can further comprise a transistor formed on the first semiconductor layer, wherein the bulk semiconductor layer can act as a back gate for the transistor.

Thanks to such approach, it is possible to achieve a good control over the channel of the transistors.

In some embodiments, the first semiconductor layer can be any of Si, and/or strained Si, and/or SiGe, and/or Ge, and/or III-V layers and/or the bulk semiconductor layer can be Si, and/or the insulation layer can be Silicon Oxide.

Thanks to such approach, it is possible to form a semiconductor structure with standard processes, thereby reducing the manufacturing costs. Also, it is possible to achieve good performances of transistors formed on the first semiconductor layer.

Moreover, the object of the present invention is also achieved by the method for manufacturing a semiconductor structure, the semiconductor structure comprising a first semiconductor layer; a bulk semiconductor layer; and an insulation layer between the first semiconductor layer and the bulk semiconductor layer; comprising the steps of a first implant carried out in a first implanted region that is at least partially within the insulation layer; and a second doping implant in a second doped region that is at least partially within the bulk semiconductor layer; wherein the first implant step is carried out so that the first implanted region has an implant profile that shows a maximum within the insulation layer and a tail extending within the bulk semiconductor layer so as to inhibit the diffusion of a second doping material of the second doped region within the insulation layer.

Thanks to such approach, it is possible to manufacture the semiconductor structure having good electrical characteristics, while minimizing the number of steps.

In some embodiments, the first implant step can comprise an ion-implant with an energy in the range of 5 keV to 15 keV, preferably 10 keV, and a dose in the range of 10¹³/cm² to 10⁴/cm ², preferably 3.10¹³/cm², and/or the second doping implant step can comprise an ion-implant with an energy in the range of 20 keV to 60 keV, preferably 30 keV, and a dose in the range of 10¹³/cm² to 2.10¹⁴/cm², preferably 5.10¹³/cm².

Thanks to such approach, the desired doping profiles for obtaining good electrical characteristics of the semiconductor structure can be obtained.

### BRIEF DESCRIPTION OF THE DRAWINGS

The invention will be described in more detail by way of examples hereinafter using advantageous embodiments and with reference to the drawings. The described embodiments are only possible configurations in which the individual features may, however, as described above, be implemented independently of each other or may be omitted. Equal elements illustrated in the drawings are provided with equal reference signs. Parts of the description relating to equal elements illustrated in the different drawings may be left out. In the drawings:

FIGS. 1a to 1f are schematic views of a semiconductor structure and a method for manufacturing of a semiconductor structure in accordance with the present invention;

FIG. 2 is a schematic view of the doping profile of a semiconductor structure in accordance with the present invention;

FIGS. 3a and 3b are schematic illustrations of implant profiles in accordance with further embodiments of the present invention;

FIG. 4 is a schematic illustration of implant profiles in accordance with yet further embodiments of the present invention; and

FIGS. 5a to 5d are schematic views of a semiconductor structure in accordance with the state of the art.

### DETAILED DESCRIPTION

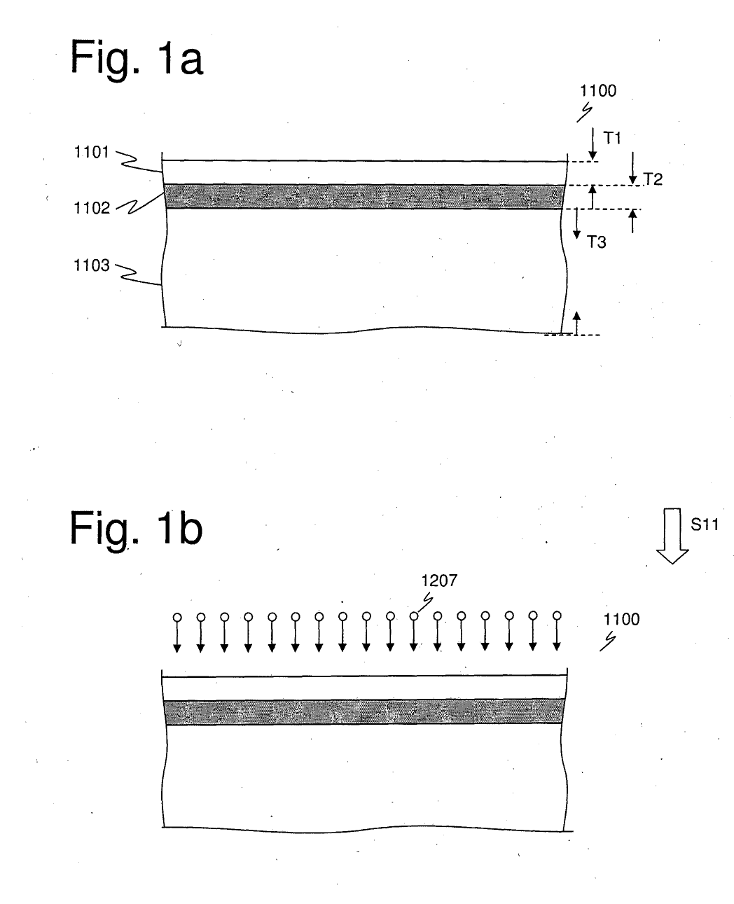

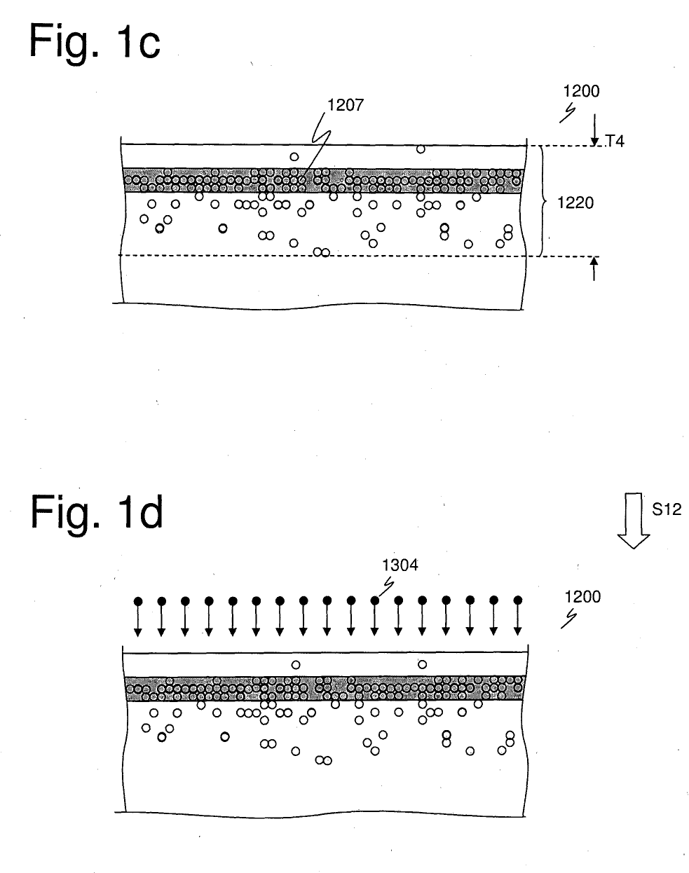

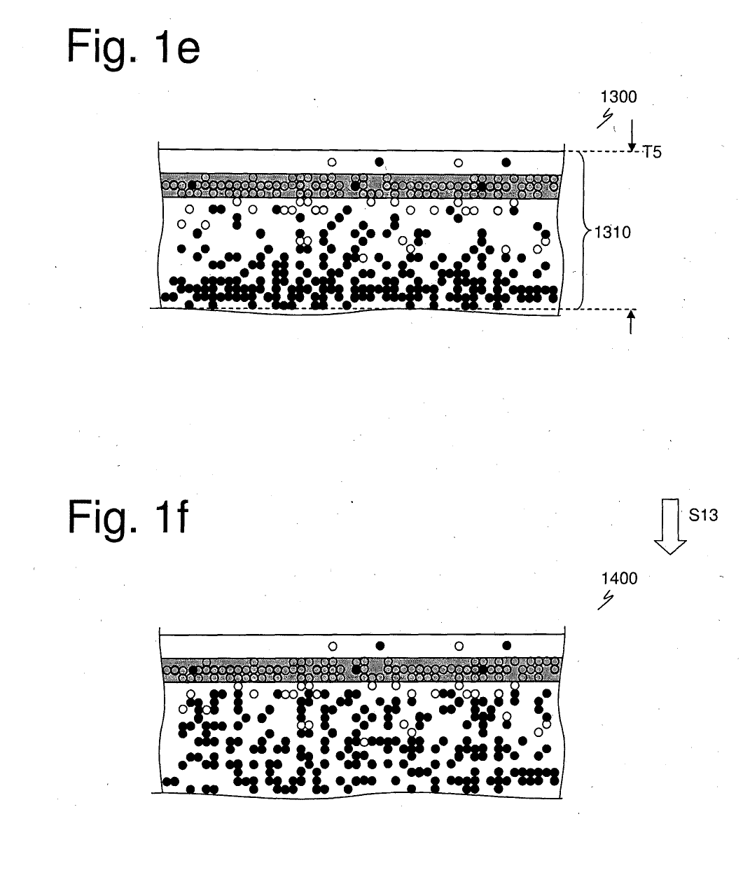

A semiconductor structure and a manufacturing method in accordance with the present invention will now be described with reference to FIGS. 1a to 1f.

As can be seen in FIG. 1a, a semiconductor structure 1100 includes a first semiconductor layer 1101, a bulk semiconductor layer 1103, and an insulation layer 1102 between the first 1101 and the bulk 1103 semiconductor layer. The first semiconductor layer 1101 can be any of Silicon, and/or strained Si, and/or SiGe, and/or Ge, and/or III-V layers. The insulation layer 1102 can be Silicon Oxide. The bulk semiconductor layer 1303 can be Silicon.

The first semiconductor layer 1101 has a thickness T1 in the range of 8 nm to 20 nm, preferably 12 nm. The insulation layer 1102 has a thickness T2 in the range of 8 nm to 40 nm, preferably 25 nm. The bulk semiconductor layer 1103 has a thickness T3 in the range of 750 μm to 800 μm, preferably 775 μm. Although not illustrated in FIG. 1a, the semiconductor structure could further comprise a sacrificial oxide layer above the first semiconductor layer 1101. The sacrificial oxide layer may have a thickness in the range of 2 nm to 5 nm, preferably 2 nm. The sacrificial oxide layer protects the first semiconductor layer 5101 from the possible contamination during ion implantation steps.

The thicknesses of the first semiconductor layer 1101 and the insulation layer 1102 are such to provide improved electrical parameters for the fabricated devices. Based on these thickness values, the parameters of the subsequent B and F implants, such as energies and doses, are adjusted accordingly.

The semiconductor structure 1100 may, e.g., be obtained by a SMARTCUT® process. More specifically, this implies providing the semiconductor structure by forming a first intermediate insulating layer above the bulk semiconductor layer 1103; forming a second intermediate insulation layer above a semiconductor substrate; bonding the first and the second intermediate insulation layers, thereby obtaining the insulation layer 1102, within a wafer transfer process and removing part of the semiconductor substrate, thereby obtaining the first semiconductor layer 1101.

As illustrated in FIG. 1b, during a first implant step S11, a first material 1207 is implanted in the semiconductor structure 1100, resulting in the semiconductor structure 1200 of FIG. 1c. The implantation of the first material can be done before or after Shallow Trench Isolation (STI) formation.

The first material 1207 is Fluorine or, as an alternative, Chlorine. When the first material is inserted by ion implantation, Fluorine is more advantageous since it is lighter than Chlorine.

The first material 1207 is implanted in a first implanted region 1220 at least partially extending within the insulation layer 1102 and having a thickness T4, measured from the top of the semiconductor structure 1200, of 40 nm to 80 nm, preferably 75 nm.

In this manner, as will be discussed below, the first material 1207 prevents the diffusion of a second doping material 1304 within the insulation layer 1102. This is beneficial, since the second doping material could have a negative impact on the electrical characteristics of the insulation layer 1102. Additionally, this is further beneficial since the first material 1207 has a positive beneficial effect on the insulation layer 1102. More specifically, the reliability of the metal-oxide-silicon system is improved by the incorporation of the first material 1207 into the insulation layer 1102. A generation of interface states and an accumulation of positive oxide charges during electrical stressing or irradiation are, in fact, generally reduced by using this approach.

As illustrated in FIG. 1d, during a second doping step S12, a second doping material 1304 is implanted in semiconductor structure 1200, resulting in the semiconductor structure 1300 of FIG. 1e. Although not illustrated in the figures, this doping step can be performed after STI formation.

The second doping material 1304 is any of Boron, and/or BF2, and/or B18H22 and/or other boron-containing molecular species. Atomic Boron is preferred since it has the lowest mass compared to other boron-containing molecular species. The second doping material 1304 is implanted in a second doped region 1310 at least partially extending within the bulk semiconductor layer 1303 and having a thickness T5, measured from the top of the semiconductor structure 1200, of 150 nm to 400 nm, preferably 200 nm.

As illustrated in FIG. 1f, during a step S13, the second doping material 1304 diffuses in the semiconductor structure 1300, resulting in the semiconductor structure 1400 of FIG. 1f. The diffusion of the second doping material 1304 can be accelerated by the presence of high-temperature steps, after step S13, in the subsequent transistors formation.

However, the diffusion of the second doping material 1304 is limited by the presence of the first material 1207. Accordingly, the degradation of the electrical characteristics of the insulation layer 1102 due to the diffusion of the second doping material 1304 from the bulk semiconductor layer 1103 into the insulation layer 1102 is prevented by the presence of the first material 1207.

Even more specifically, the tail of the first material 1207 extending from the insulation layer 1102 to the bulk semiconductor layer 1103 prevents the diffusion.

Additionally, the presence of the first material 1207 within the insulation layer 1102 improves the electrical characteristics of the insulation layer 1102 as discussed above.

Accordingly, the first implanted region 1220 achieves a synergetic effect in
(i) preventing the diffusion of the second doping material 1304 into the insulation layer 1102 and in
(ii) improving the electrical characteristics of the insulation layer 1102.

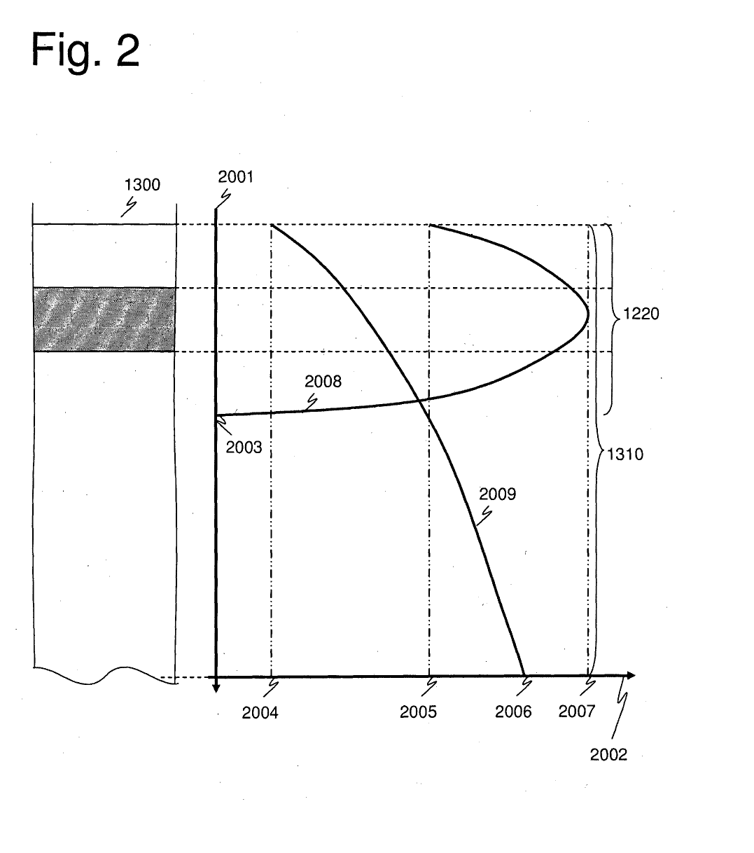

With reference to FIG. 2, a schematic profile of the first region 1220 and second doped region 1310 will now be described.

As can be seen in FIG. 2, a schematic view of the semiconductor structure 1300 (on the left side) is placed side by side to a profile chart (on the right side). The schematic view of the semiconductor structure 1300 does not include the atoms of the first material and the second doping material, for ease of interpretation, since their distribution profile is already indicated in the profile chart. The profile chart is composed of a depth axis 2001, extending in the depth direction of the semiconductor structure 1300, and of a concentration axis 2002, representing the concentration of a given material at a given depth of the semiconductor structure 1300. The concentration axis 2002 is intended as a logarithmic scale. The depth axis 2001 is intended as a linear scale.

Two solid lines in the profile chart illustrate the profile of the first implanted region 1220 and of the second doped region 1310. The dashed lines extending from the semiconductor structure 1300 into the profile chart represent the depth levels of the first semiconductor layer 1101, the insulation layer 1102 and the bulk semiconductor layer 1103. The dot and dash lines represent different values of the two solid lines.

More specifically, the first solid line 2008 illustrates the material concentration profile of the first implanted region 1220. As can be seen, the first implanted region 1220 has a first low concentration value 2005 and a first high concentration value 2007. More specifically, the first low concentration 2005 is the concentration of the first implanted region 1220 at the top surface of the first semiconductor layer 1101. The profile of the first implanted region 1220 then gradually rises, as the depth into the semiconductor structure 1300 increases to a value corresponding to the first high concentration 2007. From there on, as the depth increases, the concentration of the first implanted region 1220 gradually decreases to a value corresponding to 10¹⁷ at/cm³, at a depth corresponding to a first implanted region thickness 2003, substantially corresponding to thickness T4 in FIG. 1c.

Thus, the first implanted region 1220 has an implant profile that shows a maximum, that is to say the first high concentration 2007, within the insulation layer 1102, and a tail extending within the bulk semiconductor layer 1103.

The maximum of the implant profile can be advantageously located in the median plane of the insulation layer 1102.

The first low concentration 2005 could have a value in the range of 10¹⁷ at/cm³ to 3.10¹⁸ at/cm³, preferably 10¹⁸ at/cm³. The first high concentration 2007 could have a value in the range of 10¹⁸ at/cm³ to 10¹⁹ at/cm³, preferably 5.10¹⁸ at/cm³. The first implanted region thickness 2003 could have a value in the range of 40 nm to 80 nm, preferably 75 nm.

For an insulation layer 1102 having a thickness of 25 nm, a first semiconductor layer 1101 having a thickness of 10 nm and a sacrificial oxide having a thickness of 2 nm, this could be achieved by a first implant step S11 having an energy in the range of 5 keV to 15 keV, preferably 10 keV, and a dose in the range of 10¹³/cm² to 10¹⁴/cm², preferably 3.10¹³/cm².

Second solid line 2009 illustrates the doping profile of the second doped region 1310. As can be seen, the second doped region 1310 has a second dopant low concentration value 2004 and a second dopant high concentration value—2006. More specifically, the second dopant low concentration 2004 is the dopant concentration of the second doped region 1310 at the top surface of first semiconductor layer 1101. The dopant profile of the second doped region 1310 then gradually rises, as the depth into semiconductor structure 1300 increases, to a value corresponding to the second dopant high concentration 2006. From there on, it decreases gradually, as the depth into semiconductor structure 1300 increases.

The second dopant low concentration 2004 could have a value in the range of 10¹⁶/cm³ to 5.10¹⁷/cm³, preferably 2.10¹⁷/cm³. The second dopant high concentration 2006 could have a value in the range of 10¹⁸ /cm³ to 10¹⁹/cm³, preferably 4.10¹⁸/cm³.

For an insulation layer 102 having a thickness of 25 nm, a first semiconductor layer 1101 having a thickness of 10 nm and a sacrificial oxide having a thickness of 2 nm, this could be achieved by a second doping step S12 having an energy in the range of 20 keV to 60 keV, preferably 30 keV, and a dose in the range of 10¹³/cm² to 2.10¹⁴/cm², preferably 5.10¹³/cm².

The implant of the second doped region 1310 could be done after the implant of the first implanted region 1220.

As can be seen from FIG. 2, the first solid line 2008 illustrating the profile of the first implanted region 1220 extends at least partially within insulation layer 1102. Moreover, it can be noted that a large amount of the first material 1207 is implanted within insulation layer 1102 as the scale of the concentration axis is logarithmic. At the same time, second solid line 2009 illustrating the doping profile of the second doped region 1310 extends at least partially within the bulk semiconductor layer 1103. Moreover, it can be noted that a large amount of second doping material 1304 is implanted within the bulk semiconductor layer 1103 as the scale of the concentration axis is logarithmic. Additionally, first solid line 2008 illustrating the profile of the first implanted region 1220 has a tail extending within bulk semiconductor layer 1103.

Thanks to such a profile, the concentration of the second doping material 1304 in the bulk semiconductor layer 1103 provides a beneficial doping profile for the bulk semiconductor layer 1103 to act as a back gate for transistors formed on the first semiconductor layer 1101. Moreover, the tail concentration of the first material 1207 in the bulk semiconductor layer 1103 provides a beneficial profile for inhibiting the diffusion of the second doping material 1304 into the insulation layer 1102, thereby preventing the degradation of the electrical characteristics of the insulation layer 1102 caused by a too high amount of the second doping material 1304. Still additionally, the concentration of the first material 1207 in the insulation layer 1102 provides a beneficial profile for improving the electrical characteristics of the insulation layer 1102.

Accordingly, a synergetic effect of the two profiles results in more than two beneficial effects.

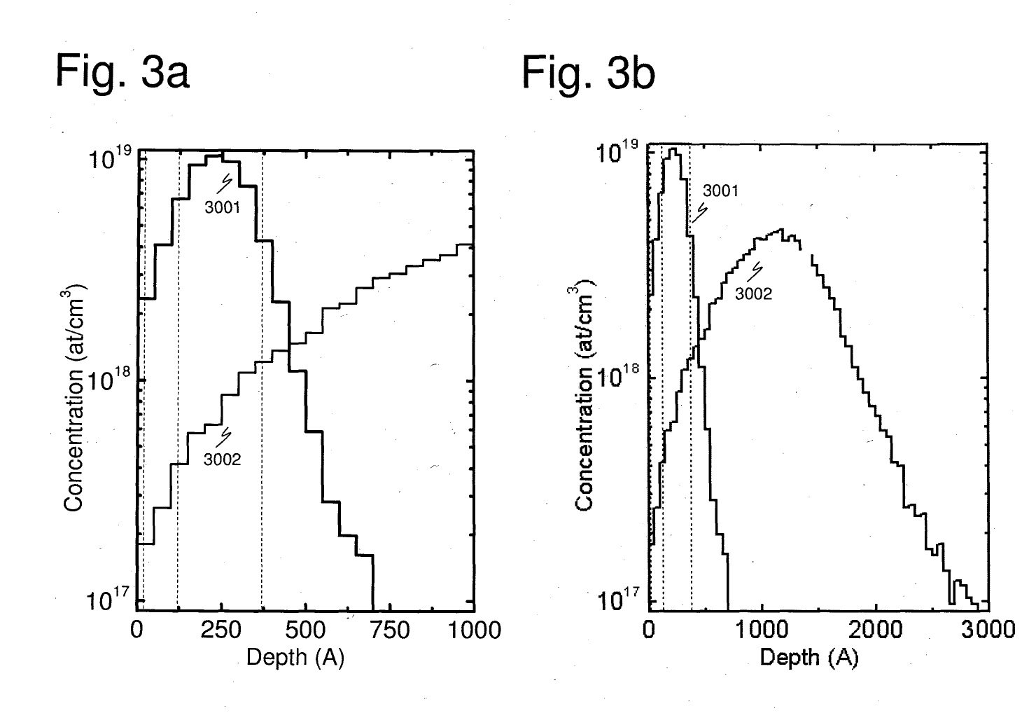

FIGS. 3a and 3b are schematic illustrations of further embodiments in accordance with the present invention. In particular, they illustrate concentration profiles resulting from steps S11 and S12 when using Fluorine as the first material 1207 and Boron as the second doping material 1304.

More specifically, they illustrate the case in which the insulation layer 1102 has a thickness of 25 nm, the, first semiconductor layer 1101 has a thickness of 10 nm and the sacrificial oxide has a thickness of 2 nm, while the bulk semiconductor layer 1103 is Silicon. In both FIGS. 3a and 3b, the vertical axis indicates the concentration, in atoms/cm³, while the horizontal axis indicates the depth, from the top of semiconductor structure not including the sacrificial oxide.

In both FIGS. 3a and 3b, the Fluorine profile 3001 is implanted with an energy of 10 keV and a dose of 3.10¹³/cm², while the Boron profile 3002 is implanted with an energy of 30 keV and a dose of 5.10¹³/cm².

Although the above embodiments have been described with reference to two implant steps S11 and S12, it has to be understood that the two implant steps S11 and S12 do not necessarily imply only two implants, but each could be performed by one or more sub-implant steps.

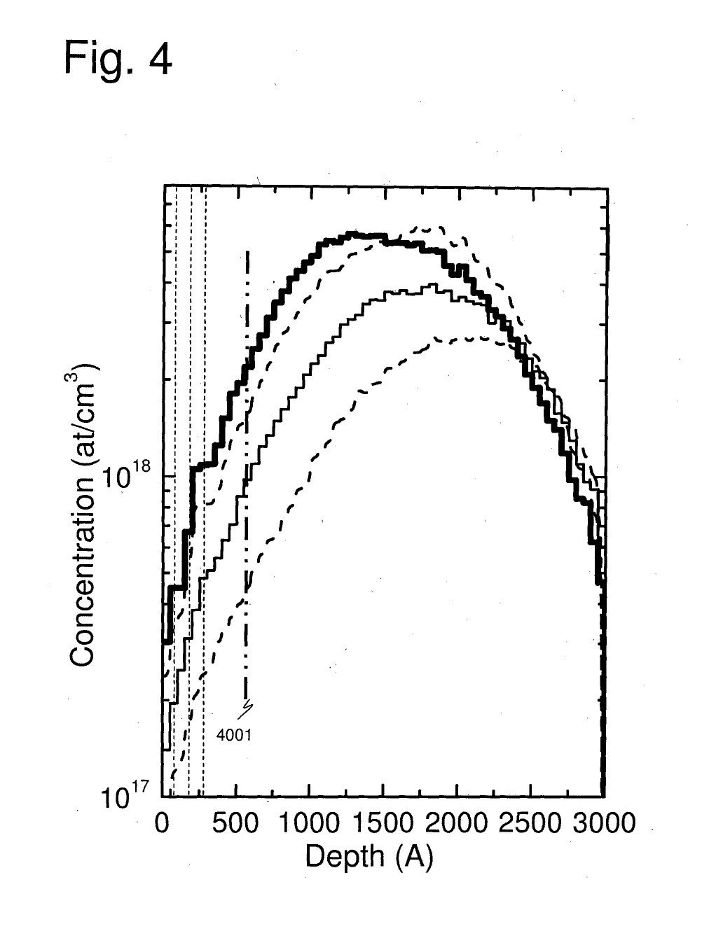

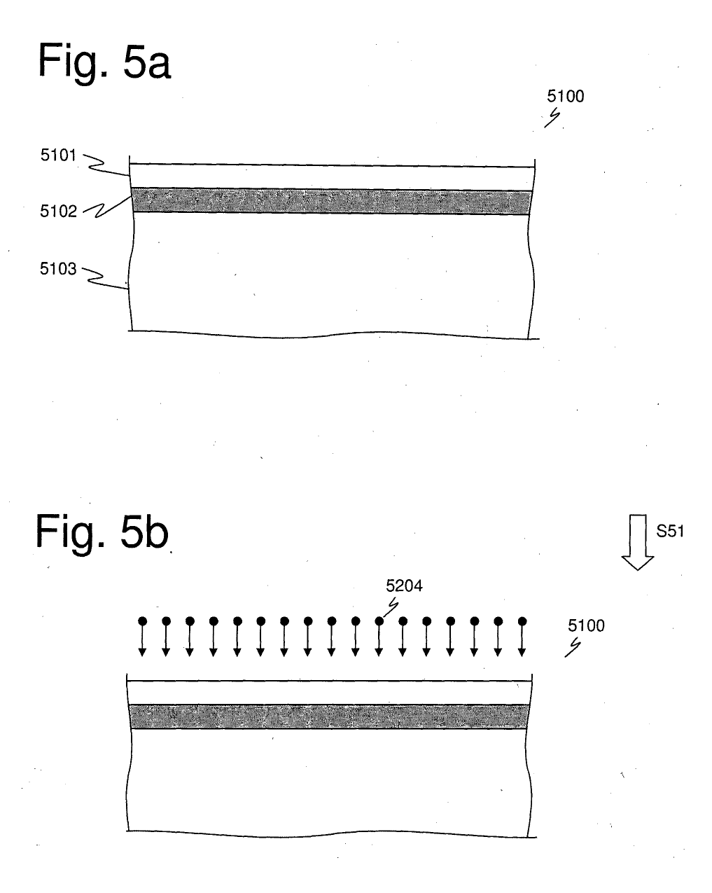

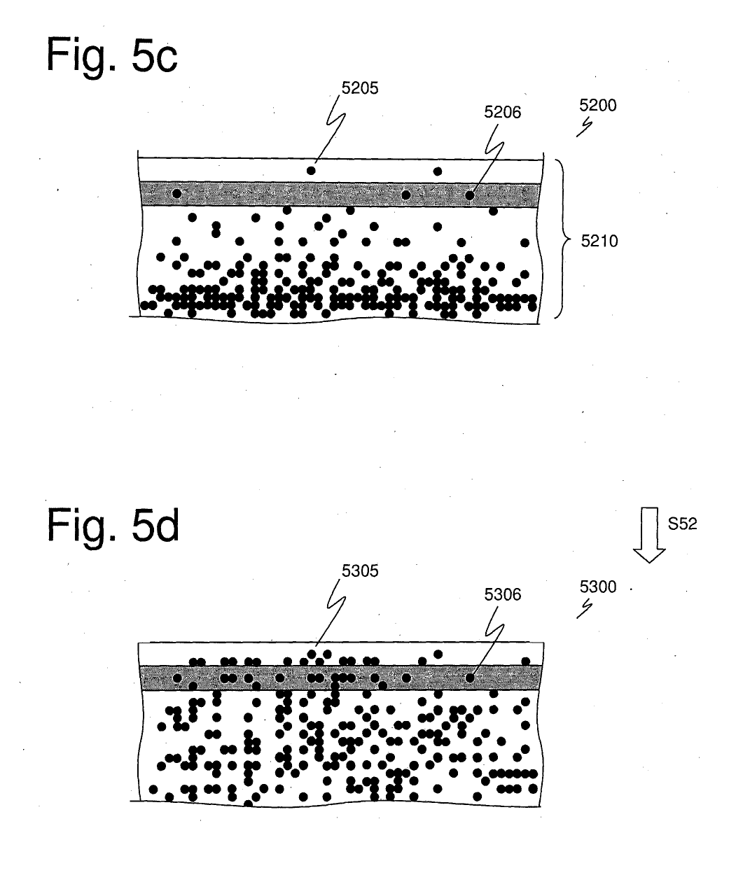

For instance, for step S12 including a Boron doping, chain implants, i.e., the combination of two Boron implants with different energies, can be advantageously used. This is illustrated in FIG. 4. A similar approach, although not illustrated, can be used for the first material 1207.

More specifically, FIG. 4 illustrates an embodiment in which a Boron implant step S12 is performed by one or more combined sub-steps. In particular, the implant profile is performed under the following conditions: the insulation layer 1102 having a thickness of 10 nm, the first semiconductor layer 1101 having a thickness of 10 nm arid the sacrificial oxide having a thickness of 8 nm, while the bulk semiconductor layer 1103 is Silicon.

Each curve is formed by a combination of two implants. In particular, along line 4001, from the bottom of the graph moving upward, each line is formed by the following implant combinations: 40 keV with a dose of 10¹³/cm² and 60 keV with a dose of 4.10¹³/cm², 35 keV with a dose of 2.10¹³/cm² and 55 keV with a dose of 5.10¹³/cm², 30 keV with a dose of 2.10¹³/cm² and 50 keV with a dose of 8.10¹³/cm², 30 keV with a dose of 4.10¹³/cm² and 50 keV with a dose of 6.10¹³/cm².

In addition, an additional implant step (not shown in the figures) with carbon and/or fluorine as an implant species could be realized, at a depth deeper than the first implanted region 1220. The carbon implant specie is preferred since its atomic mass is lower than that of fluorine. The implanted carbon profile should coincide with that of the boron profile, i.e., ion-implant with an energy in the range of 20 keV to 60 keV, preferably 30 keV. The dose range for carbon implants could be 5.10¹³/cm² to 10¹⁴/cm², preferably 10¹⁴/cm². This would provide the beneficial advantage of further inhibiting the diffusion of the second doping material 1304.

1.-12. (canceled)

13. A semiconductor structure, comprising:
a first semiconductor layer;
a bulk semiconductor layer;
an insulation layer between the first semiconductor layer and the bulk semiconductor layer;
a first implanted region that is at least partially within the insulation layer; and
a second doped region that is at least partially within the bulk semiconductor layer;
wherein the first implanted region has an implant profile that shows a maximum within the insulation layer and a tail extending within the bulk semiconductor layer so as to inhibit the diffusion of a second doping material of the second doped region within the insulation layer.

14. The semiconductor structure of claim 13, wherein the second doping material of the second doped region comprises boron.

15. The semiconductor structure of claim 14, wherein the second doping material of the second doped region comprises at least one of B, BF₂, and B₁₈H₂₂.

16. The semiconductor structure of claim 15, wherein a first material of the first implanted region comprises at least one of fluorine and chlorine.

17. The semiconductor structure of claim 13, wherein a first material of the first implanted region comprises at least one of fluorine and chlorine.

18. The semiconductor structure of claim 13, wherein the first implanted region has a thickness in the range of 40 nm to 80 nm.

19. The semiconductor structure of claim 18, wherein the first implanted region has a thickness of about 75 nm.

20. The semiconductor structure of claim 13, wherein the second doped region has a thickness in the range of 150 nm to 400 nm.

21. The semiconductor structure of claim 20, wherein the second doped region has a thickness of about 200 nm.

22. The semiconductor structure of claim 13, wherein the first semiconductor layer has a thickness in the range of 8 nm to 20 nm, the bulk semiconductor layer has a thickness in the range of 750 μm to 800 μm, and the insulation layer has a thickness in the range of 8 nm to 40 nm.

23. The semiconductor structure of claim 13, further comprising a transistor formed on the first semiconductor layer, wherein the bulk semiconductor layer is configured as a back gate for the transistor.

24. The semiconductor structure of claim 13, wherein the first semiconductor layer comprises at least one of Si, strained Si, SiGe, Ge, and a III-V semiconductor material.

25. The semiconductor structure of claim 13, wherein the bulk semiconductor layer is Si.

26. The semiconductor structure of claim 13, wherein the insulation layer is silicon oxide.

27. A method for manufacturing a semiconductor structure that includes a first semiconductor layer, a bulk semiconductor layer, and an insulation layer between the first semiconductor layer and the bulk semiconductor layer, the method comprising:
implanting, in an implant process, a first material into a first implanted region that is at least partially within the insulation layer; and
implanting, in a doping process, a second material into a second doped region that is at least partially within the bulk semiconductor layer;
wherein the implant process is carried out so that the first implanted region has an implant profile having a maximum within the insulation layer and a tail extending within the bulk semiconductor layer so as to inhibit the diffusion of the second material of the second doped region into the insulation layer.

28. The method of claim 27, wherein the implant process comprises an ion-implant with an energy in the range of 5 keV to 15 keV, and a dose in the range of 10¹³/cm² to 10¹⁴/cm².

29. The method of claim 28, wherein the doping process comprises an ion-implant with an energy in the range of 20 keV to 60 keV, and a dose in the range of 10¹³/cm² to 2.10¹⁴/cm².

30. The method of claim 27, wherein the doping process comprises an ion-implant with an energy in the range of 20 keV to 60 keV, and a dose in the range of 10¹³/cm² to 2.10¹⁴/cm².
